(19) United States
(12) Patent Application Publication
(10) Pub. No.: US 2024/0404825 A1
(43) Pub. Date: Dec. 5, 2024

(54) METHODS OF MAKING SEMICONDUCTOR STRUCTURES, SEMICONDUCTOR STRUCTURES, AND SEMICONDUCTOR PROCESSING SYSTEMS AND COMPUTER PROGRAM PRODUCTS FOR MAKING SEMICONDUCTOR STRUCTURES

(71) Applicant: ASM IP Holding B.V., Almere (NL)

(72) Inventor: Ernesto Suarez, Scottsdale, AZ (US)

(21) Appl. No.: 18/676,760

(22) Filed: May 29, 2024

Related U.S. Application Data
(60) Provisional application No. 63/504,970, filed on May 30, 2023.

(51) Int. Cl. H01L 21/02; C23C 16/52

(52) U.S. Cl. CPC H01L 21/02532; C23C 16/52; H01L 21/02381; H01L 21/02579; H01L 21/0262

(57) ABSTRACT

A method of making a semiconductor structure includes seating a substrate within a chamber arrangement, depositing a boron-doped silicon germanium layer onto the substrate, and depositing a boron-doped silicon layer onto the boron-doped silicon germanium layer. Deposition of the boron-doped silicon layer includes ceasing flow of a boron-containing precursor to the chamber arrangement; decreasing flow of a germanium-containing precursor to the chamber arrangement; increasing flow of a silicon-containing precursor to the chamber arrangement; ceasing, after increasing flow of the silicon-containing precursor, flow of the germanium-containing precursor to the chamber arrangement; and resuming flow of the boron-containing precursor to the chamber arrangement. Semiconductor structures as well as semiconductor processing systems and computer program products for making semiconductor structures are also described.

### CROSS-REFERENCE TO RELATED APPLICATION(S)

This application claims the benefit of U.S. Provisional Application 63/504,970 filed on May 30, 2023, the entire contents of which are incorporated herein by reference.

### FIELD OF INVENTION

The present disclosure generally relates to fabricating semiconductor devices, and more particularly to depositing layers to form semiconductor structures used in the fabrication of semiconductor devices.

### BACKGROUND OF THE DISCLOSURE

Semiconductor devices, such as logic and memory devices having three dimensional architectures, are commonly formed by depositing material layers onto substrates. Material layer deposition is generally accomplished by supporting a substrate within a reactor, providing one or more precursors to the reactor, and exposing the substrate to the one or more precursor under conditions selected to cause a desired material layer to deposit onto the surface of the substrate. Once the material layer develops desired properties (e.g., resistivity and/or thickness) flow of the one or more precursor ceases, and substrate generally removed from the reactor to undergo further processing, as appropriate for the semiconductor device being fabricated using the layer. The precursors are typically selected according to impart desired properties into the material layer being deposited onto the substrate, and may include dopants and/or alloying constituents for incorporation into the material layer.

In some material layer deposition operations constituents may compete with one another for incorporation into the material layer being formed on the substrate. For example, under certain processing conditions an alloying constituent such as germanium (Ge) may have a greater affinity for incorporation than matrix constituent, such as silicon. Similarly, certain dopant constituents may have greater affinity for incorporation than both the alloying constituent, such as in certain processes employing boron (B). This can lead to within-layer constituent concentration variation, such as at the termination of deposition where lingering constituents having greater incorporation affinity may result in the material layer having greater concentration of the constituent at the terminal surface of the material layer, as shown at interface A and interface B in FIG. 9. Without being bound by a particular theory or mode of operation, it is believed that energy state may influence incorporation rate, constituents requiring lower activation energy to incorporating more readily into the growth face of a developing layer than constituents requiring greater activation energy. As a consequence, process conditions are typically selected to match incorporation rate of the various layer constituents to the desired properties of the developing layer.

Various techniques may be employed to manage constituents with different incorporation affinity. For example, mass flow of precursors providing the various constituents may be limited such incorporation rate is constrained by the mass of available constituent atoms within the reactor atmosphere. In multilayer processing regimes wherein two or more layers have different compositions are deposited sequentially within the reactor, the reactor atmosphere may be purged between deposition of the first layer and deposition of the second layer, the purging removing residual precursor and constituents employed for deposition of the first layer from the reactor prior to deposition of the second layer to limit their incorporation in the second layer.

Such systems and methods for making semiconductor devices have generally been acceptable for their intended purpose. However, there remains a need in the art for improved methods of making semiconductor structures, semiconductor structures, semiconductor processing systems, and related computer program products for making semiconductor structures. The present disclosure provided a solution to this need.

### SUMMARY OF THE DISCLOSURE

A method of making a semiconductor structure is provided. The method includes seating a substrate within a chamber arrangement, depositing a boron-doped silicon germanium (SiGe:B) layer overlaying the substrate, and depositing a boron-doped silicon (Si:B) layer overlying the boron-doped silicon germanium layer. Deposition of the boron-doped silicon layer is accomplished by ceasing flow of a boron-containing precursor to the chamber arrangement; decreasing flow of a germanium-containing precursor to the chamber arrangement; increasing flow of a silicon-containing precursor to the chamber arrangement; ceasing, after increasing flow of the silicon-containing precursor, flow of the germanium-containing precursor to the chamber arrangement; and resuming flow of the boron-containing precursor to the chamber arrangement.

In addition to one or more of the features described above, or as an alternative, further examples of the method may include that the SiGe:B layer has a SiGe:B layer boron concentration, that the Si:B layer has a Si:B layer boron concentration, and that the Si:B layer boron concentration is greater than the SiGe:B layer boron concentration.

In addition to one or more of the features described above, or as an alternative, further examples of the method may include depositing a silicon germanium (SiGe) layer onto the substrate. The SiGe:B layer may be deposited onto the SiGe layer.

In addition to one or more of the features described above, or as an alternative, further examples of the method may include flowing a silicon-containing layer precursor to the chamber arrangement continuously and without interruption during deposition of both the SiGe:B layer and the Si:B layer.

In addition to one or more of the features described above, or as an alternative, further examples of the method may include that the first SiGe:B layer has a first boron concentration, that the second SiGe:B layer has a second boron concentration, and that the second boron concentration is greater than the first boron concentration.

In addition to one or more of the features described above, or as an alternative, further examples of the method may include that the Si:B layer has a third boron concentration. The third boron concentration may be greater than the second boron concentration.

In addition to one or more of the features described above, or as an alternative, further examples of the method may include that the Si:B layer has a third boron concentration. The third boron concentration may be is greater than the second boron concentration.

In addition to one or more of the features described above, or as an alternative, further examples of the method may include that the first SiGe:B layer has a first germanium concentration, that the second SiGe:B layer has a second germanium concentration, and that the second germanium concentration is greater than the first germanium concentration.

In addition to one or more of the features described above, or as an alternative, further examples of the method may include that depositing the first SiGe:B layer and depositing the second SiGe:B layer includes flowing a silicon-containing layer precursor to the chamber arrangement. The silicon-containing layer precursor may be flowed continuously and without interruption during deposition of both the first SiGe:B layer and the second Si:B layer.

In addition to one or more of the features described above, or as an alternative, further examples of the method may include that depositing the SiGe:B layer includes flowing the boron-containing precursor to the chamber arrangement at a first boron-containing precursor flow rate. Flow rate of the boron-containing precursor may be increased to a second boron-containing precursor flow rate during deposition of the SiGe:B layer, the second boron-containing precursor flow rate greater than the first boron-containing precursor flow rate.

In addition to one or more of the features described above, or as an alternative, further examples of the method may include that the substrate has a silicon surface portion and a dielectric surface portion, and method may further include an etchant to the chamber arrangement during deposition of both the SiGe:B layer and deposition of the Si:B layer to etch the dielectric surface portion of the substrate.

In addition to one or more of the features described above, or as an alternative, further examples of the method may include defining an interface between the SiGe:B layer and the Si:B layer between ceasing flow of the boron-containing precursor and resuming flow of the boron-containing precursor to the chamber arrangement.

A semiconductor structure is provided. The semiconductor structure is formed using the method of forming a semiconductor structure as described above.

In addition to one or more of the features described above, or as an alternative, further examples of the semiconductor structure may include that the semiconductor structure includes a SiGe layer overlaying the substrate, a first SiGe:B layer overlaying the SiGe layer, a second SiGe:B layer overlaying the first SiGe:B layer, and a Si:B layer overlaying the second SiGe:B layer. The Si:B layer and the second SiGe:B layer may define a defect-free interface at an interface of the second SiGe:B layer and the Si:B layer.

In addition to one or more of the features described above, or as an alternative, further examples of the semiconductor structure may include that the SiGe layer overlays the substrate, the first SiGe:B layer overlays the SiGe layer, the second SiGe:B layer overlays the first SiGe:B layer, and the Si:B layer overlays the second SiGe:B layer.

In addition to one or more of the features described above, or as an alternative, further examples of the semiconductor structure may include that the first SiGe:B layer is deposited onto (e.g., directly onto) the SiGe layer, the second SiGe:B layer is deposited onto (e.g., directly onto) the first SiGe:B layer, and the Si:B layer is deposited onto (e.g., directly onto) the second SiGe:B layer.

A semiconductor processing system is provided. The semiconductor processing system includes a precursor delivery arrangement, a chamber arrangement with a substrate support connected to the precursor delivery arrangement, and a controller operably connected to the precursor delivery arrangement and the chamber arrangement. The controller is responsive to instructions recorded on a memory to seat a substrate within the chamber arrangement, deposit a SiGe:B layer overlaying the substrate, and deposit a Si:B layer overlaying the SiGe:B layer. The Si:B layer is deposited by ceasing flow of a boron-containing precursor to the chamber arrangement during deposition of the SiGe:B layer; decreasing flow of a germanium-containing precursor to the chamber arrangement during deposition of the SiGe:B layer; and increasing flow of a silicon-containing precursor to the chamber arrangement coincident with at least one of the ceasing flow of the boron-containing precursor and decreasing flow of the germanium-containing precursor to the chamber arrangement. Flow of the germanium-containing precursor ceases subsequent to increasing flow of the silicon-containing precursor to the chamber arrangement, and flow of the boron-containing precursor then is thereafter resumed to the chamber arrangement subsequent to ceasing flow of the germanium-containing precursor to the chamber arrangement.

In addition to one or more of the features described above, or as an alternative, further examples of the semiconductor processing system may include that the SiGe:B layer is a first SiGe:B layer and that the instructions further cause the controller to deposit a SiGe layer onto the substrate, deposit the first SiGe:B layer onto the first SiGe layer, deposit a second SiGe:B layer onto the first SiGe:B layer, and deposit the Si:B layer onto the second SiGe:B layer.

In addition to one or more of the features described above, or as an alternative, further examples of the semiconductor processing system may include the instructions further cause the controller to flow an etchant to the chamber arrangement during deposition of at least one of the SiGe layer, the first SiGe:B layer, the second SiGe:B layer, and the Si:B layer; and etch a dielectric surface portion of the substrate during deposition of at least one of the SiGe layer, the first SiGe:B layer, the second SiGe:B layer, and the Si:B layer overlaying a silicon surface portion of the substrate.

A computer program product is provided. The computer program product includes a memory with a non-transitory machine-readable medium having instructions recorded on that cause a controller operably connected to a precursor delivery arrangement and a chamber arrangement to seat a substrate within the chamber arrangement, deposit a SiGe:B layer overlaying the substrate, and deposit a Si:B layer overlying the SiGe:B layer. The Si:B layer may be deposited by ceasing flow of a boron-containing precursor to the chamber arrangement; decreasing flow of a germanium-containing precursor to the chamber arrangement; increasing flow of a silicon-containing precursor to the chamber arrangement; ceasing, after increasing flow of the silicon-containing precursor, flow of the germanium-containing precursor to the chamber arrangement; and resuming flow of the boron-containing precursor to the chamber arrangement subsequent to ceasing flow of the germanium-containing precursor to the chamber arrangement.

This summary is provided to introduce a selection of concepts in a simplified form. These concepts are described in further detail in the detailed description of examples of the disclosure below. This summary is not intended to identify key features or essential features of the claimed subject matter, nor is it intended to be used to limit the scope of the claimed subject matter.

### BRIEF DESCRIPTION OF THE DRAWING FIGURES

These and other features, aspects, and advantages of the invention disclosed herein are described below with reference to the drawings of certain embodiments, which are intended to illustrate and not to limit the invention.

FIG. 1 is a schematic view of a semiconductor processing system in accordance with the present disclosure, showing a semiconductor structure being formed on a substrate seated within a chamber arrangement using precursor provided by a precursor delivery arrangement;

FIGS. 2 and 3 are schematic views of the precursor delivery arrangement and gas delivery arrangement of FIG. 1, showing elements of the precursor delivery arrangement and the chamber arrangement according to examples of the present disclosure;

FIG. 4 is a schematic cross-sectional side view of the semiconductor structure of FIG. 1, showing interfaces between the boron-containing layers;

FIGS. 5-8 are sectional side views of the semiconductor structure of FIG. 1, sequentially showing layers being deposited to form the semiconductor structure;

FIGS. 9 and 10 are charts of boron concentration as a function of depth within a semiconductor structure formed without and with precursor sequencing; and

FIGS. 11-14 are a block diagram of a method of forming the semiconductor structure of FIG. 1 in accordance with the present disclosure, showing operations of the method according to an illustrative and non-limiting example of the present disclosure.

It will be appreciated that elements in the figures are illustrated for simplicity and clarity and have not necessarily been drawn to scale. For example, the relative size of some of the elements in the figures may be exaggerated relative to other elements to help improve understanding of illustrated embodiments of the present disclosure.

### DETAILED DESCRIPTION OF EXEMPLARY EMBODIMENTS

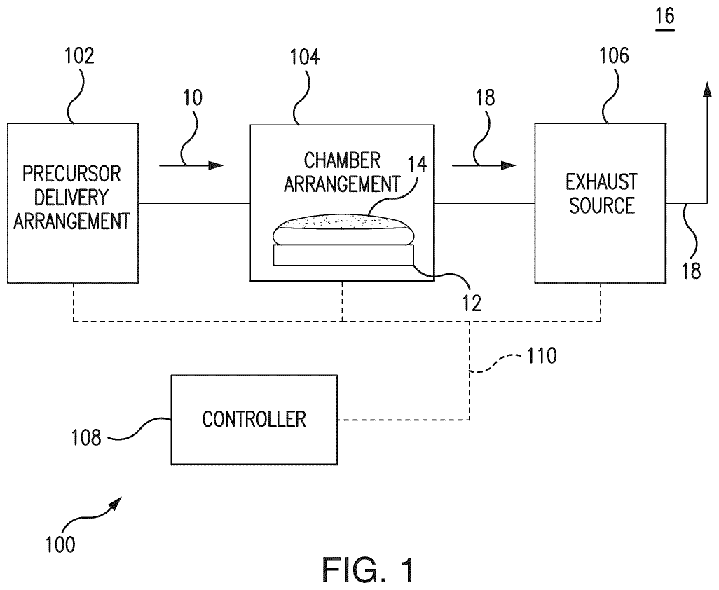

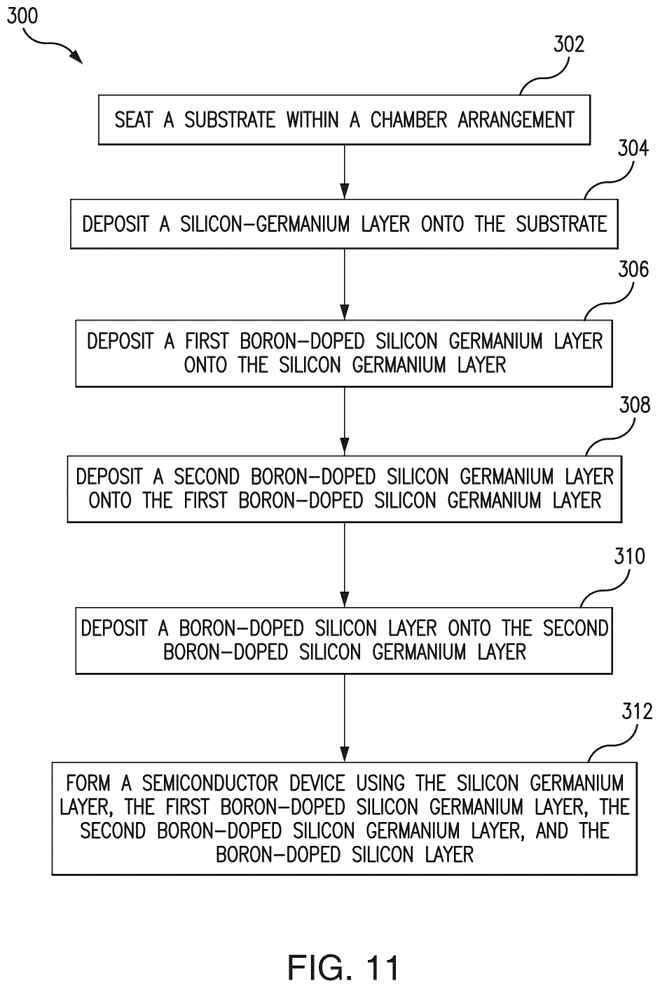

Reference will now be made to the drawings wherein like reference numerals identify similar structural features or aspects of the subject disclosure. For purposes of explanation and illustration, and not limitation, a partial view of an example of a method of making a semiconductor structure in accordance with the present disclosure is shown in FIG. 11 and is designated generally by reference character 300. Other examples of methods of making semiconductor structures, semiconductor structures, and semiconductor processing systems and computer program products for making semiconductor structures appear in FIGS. 1-8 and 12-14, as will be described. The systems and methods of the present disclosure may be used to deposit material layers onto substrates during the fabrication of semiconductor structures, such as doped silicon-containing material layers formed using epitaxial deposition techniques for source and drain portions of semiconductor devices having three-dimensional architectures. However, the present disclosure is limited to any particular type of material, semiconductor device architecture, or semiconductor device in general.

Referring to FIG. 1, the semiconductor processing system 100 is shown. The semiconductor processing system 100 includes a precursor delivery arrangement 102, a chamber arrangement 104, an exhaust arrangement 106, and a controller 108. The precursor delivery arrangement 102 is connected to the chamber arrangement 104 and is configured to provide a precursor 10 to the chamber arrangement 104. The chamber arrangement 104 is connected to the exhaust arrangement 106, fluidly couples the precursor delivery arrangement 102 to the exhaust arrangement 106, and is configured to support a substrate 2 during the forming of a semiconductor structure 200 on the substrate 2. The exhaust arrangement 106 is fluidly coupled to an external environment 16 outside of the semiconductor processing system 100 and is configured to communicate a flow or residual precursor and/or reaction products 18 generated during deposition of the layer 14 onto the substrate 12 to the external environment 16 outside of the semiconductor processing system 100, for example using one or more vacuum pump configured to maintain the substrate 2 within a reduced pressure atmosphere (e.g., less than 760 Torr). The controller 108 is operably connected to the semiconductor processing system 100, for example through a wired or wireless link 110, and in this respect may be in communication with at least one of the precursor delivery arrangement 102, the chamber arrangement 104, and the exhaust arrangement 106. Although shown and described herein as including certain elements and having a specific arrangement, it is to be understood and appreciated that the semiconductor processing system 100 may include additional elements and/or omit elements shown and described herein and remain within the scope of the present disclosure.

As used herein the term “substrate” may refer to any underlying material or materials, including any underlying material or materials that may be modified, or upon which, a device, a circuit, or a film may be formed. A substrate may be continuous or non-continuous; rigid or flexible; solid or porous; and combinations thereof. A substrate may be in any form such as (but not limited to) a powder, a plate, or a workpiece. A substrate in the form of a plate may include a wafer in various shapes and sizes, for example, including 300-millimeter wafers.

A substrate may be formed from semiconductor materials, including, for example, silicon (Si), silicon-germanium (SiGe), silicon oxide (SiO₂), gallium arsenide (GaAs), gallium nitride (GaN) and silicon carbide (SiC). A substrate may include a pattern or may an unpatterned, blanket-type substrate. As examples, substrates in the form of a powder may have applications for pharmaceutical manufacturing. A porous substrate may include one or more polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, a continuous substrate may move through the process chamber such that the process continues until the end of the substrate is reached. A continuous substrate may be supplied from a continuous substrate feeding system to allow for manufacture and output of the continuous substrate in any appropriate form. Non-limiting examples of continuous substrates may include sheets, non-woven films, rolls, foils, webs, flexible materials, bundles of continuous filaments or fibers (for example, ceramic fibers or polymer fibers). A continuous substrate may also comprise a carrier or sheet upon which one or more non-continuous substrate is mounted.

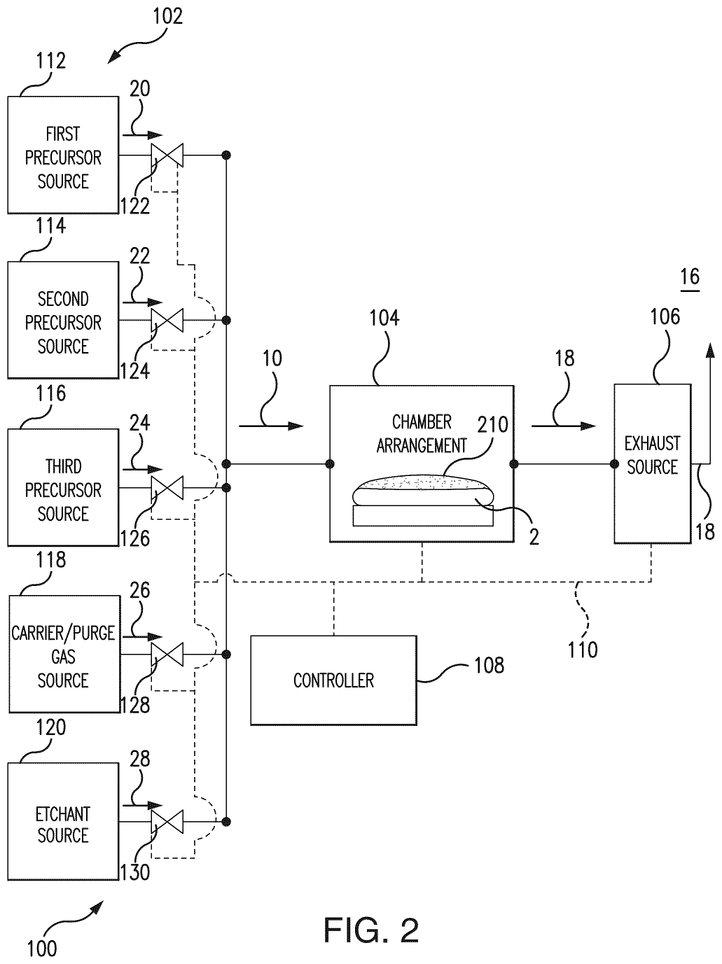

With reference to FIG. 2, the precursor delivery arrangement 102 is shown according to an example of the present disclosure. In the illustrated example the precursor delivery arrangement 102 includes a first precursor source 112, a second precursor source 114, and a third precursor source 116. As shown and described herein the precursor delivery arrangement 102 also includes a carrier/purge gas source 118 and an etchant source 120. In certain examples, the precursor delivery arrangement 102 may be as shown and described in U.S. Pat. No. 11,053,591, to Ma et al., issued Jul. 6, 2021, the contents of which are incorporated herein by reference in its entirety. Although shown and describe herein as having certain elements and a specific arrangement, it is to be understood and appreciated that the precursor delivery arrangement 102 may include other elements and/or exclude elements shown and described herein in other examples, and/or have a differing arrangement in other examples, and remain within the scope of the present disclosure.

The first precursor source 112 includes a first precursor 20 and is connected to the chamber arrangement 104 by a first precursor supply valve 122 and is configured to provide a flow of the first precursor 20 to the chamber arrangement 104 to form the semiconductor structure 200. In this respect the first precursor supply valve 122 may be operatively associated with the controller 108, and may include a mass flow controller (MFC) device and/or a diverter valve. In certain examples, the first precursor 20 may include a silicon-containing layer precursor, such as one or more non-halogenated silicon-containing precursor and/or one or more chlorinated silicon-containing layer precursor. Examples of suitable non-halogenated layer precursors include silane (SiH₄), disilane (Si₂H₆), trisilane (Si₃H₈), and tetrasilane (Si₄H₁₀). Examples of suitable halogenated silicon-containing layer precursors include dichlorosilane (H₂SiCl₂) and trichlorosilane (HCl₃Si). As will be appreciated by those of skill in the art in view of the present disclosure, the first precursor source 112 may include another other silicon-containing layer precursors and/or a mixture thereof and remain within the scope of the present disclosure.

The second precursor source 114 is connected to the chamber arrangement 104 by a second precursor supply valve 124 and configured to provide a flow of a second precursor 22 to the chamber arrangement 104 to form the semiconductor structure 200. In this respect the second precursor supply valve 124 may be similar to the first precursor supply valve 122 and also be operatively associated with the controller 108. In certain examples, the second precursor 22 may include an alloy constituent, for example, a material that cooperates with the first precursor 20 to form the layer 14 as an alloy. In this respect the second precursor 22 may include a germanium-containing material, such as a non-chlorinated germane-containing materials and/or a chlorinated germane-containing material. Examples of suitable non-chlorinated germane-containing materials include germane (GeH₄). Examples of suitable chlorinated germane-containing materials include germanium tetrachloride (GeCl₄). As will be appreciated by those of skill in the art in view of the present disclosure, other alloy constituents, such as gallium (Ga) and/or indium (In), may be employed and remain within the scope of the present disclosure. In certain examples, the first precursor may include a first material layer constituent having a lesser affinity for incorporation into a material layer forming the semiconductor structure 200 than a second material layer constituent provided by the second precursor. For example, the first precursor may provide silicon (Si) for incorporation into a material layer being deposited onto the substrate during forming of the semiconductor structure 200, and the second precursor may provide germanium (Ge) for incorporation into the material layer being deposited during the forming of the semiconductor structure 200.

The third precursor source 116 is connected to the chamber arrangement 104 by a third precursor supply valve 126 and is configured to provide a flow of a third precursor 24 to the chamber arrangement 104 to form the semiconductor structure 200. The third precursor supply valve 126 may be similar to the first precursor supply valve 122 and further operatively associated with the first precursor supply valve 122. In certain examples, the third precursor 24 may include a dopant-containing material (e.g., the second precursor 22). In this respect it is contemplated that the third precursor 24 may include a p-type dopant, such as boron (B) or gallium (Ga. Examples of suitable dopant-containing materials include diborane (B₂H₆), gallium nitrate (Ga(NO₃)₃. As will be appreciated by those of skill in the art in view of the present disclosure, other dopant-containing materials may be employed and remain within the scope of the present disclosure.

In certain examples, the third precursor may include a third material layer constituent having a greater affinity for incorporation into a material layer forming the semiconductor structure 200 than the second material layer constituent provided by the second precursor. For example, the third precursor may provide boron (B) for incorporation into a material layer being deposited onto the substrate during forming of the semiconductor structure 200, and the second precursor may provide germanium (Ge) for incorporation into the layer being deposited to form the semiconductor structure 200. The third material layer constituent may also have a greater affinity for incorporation into the layer than the first constituent being incorporated into the layer. For example, the material layer may include both silicon (Si) and boron (B), and available boron (B) may outcompete silicon (Si) for incorporation into the layer. Similarly, the material layer may include silicon (Si), germanium (Ge), and boron (B), and the boron (B) may outcompete both silicon (Si) and germanium (Ge) for incorporation into the material layer.

The carrier/purge gas source 118 and the etchant source 120 are further connected to the chamber arrangement 104 through a carrier/purge gas supply valve 128 and an etchant supply valve 130, respectively. The carrier/purge gas supply valve 128 is configured to provided provide a flow of a carrier/purge gas 28 to the chamber arrangement 104, may be similar to the first precursor supply valve 122, and may be operatively associated with the controller 108. In certain examples, the carrier/purge gas source 118 may include an inert gas and/or a noble gas. Examples of suitable inert gases include nitrogen (N₂) gas. Examples of suitable noble gases include helium (He), argon (Ar), and krypton (Kr). In accordance with certain examples, the carrier/purge gas source 118 may alternatively (or additionally) be configured to provide a flow of hydrogen (H₂) gas to the chamber arrangement 104. It is contemplated that the carrier/purge gas 28 may be employed to throttle concentration of one or more of the first precursor 20, the second precursor 22, the third precursor 24, and/or an etchant 26 provided to the chamber arrangement 104 during forming of the semiconductor structure 200 as well as to provide a purge atmosphere within the chamber arrangement 104. As will be appreciated by those of skill in the art in view of the present disclosure, other carrier/purge gases and/or etchant may be employed and remain within the scope of the present disclosure.

The etchant source 120 is configured to provide the etchant 26 to the chamber arrangement 104 through the etchant supply valve 130. The etchant supply valve 130 may be similar to the first precursor supply valve 122 and operatively associated with the controller 108, for example for throttling the flow of the etchant 26 provided to the chamber arrangement 104. Examples of suitable etchants include halide-containing materials, such as materials containing fluorine (F) or chlorine (CI). Examples of suitable halide-containing materials include hydrofluoric (HF) acid, hydrochloric (HCl) acid, and/or chlorine (Cl₂) gas. As will be appreciated by those of skill in the art in view of the present disclosure, the etchant 26 may be employed to impart selectivity to one or more deposition processes employed within the chamber arrangement 104 to form the semiconductor structure 200, for example, to etch amorphous or polycrystalline material deposited onto the substrate 2 more rapidly than epitaxial material of substantially equivalent composition.

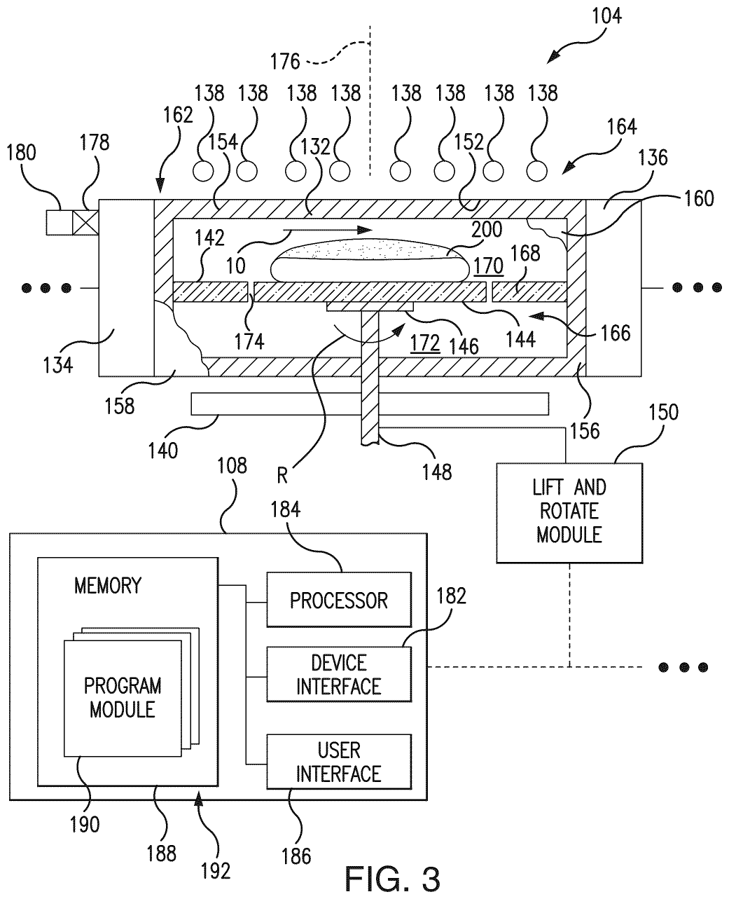

With reference to FIG. 3, the chamber arrangement 104 and the controller 108 are shown according to an example of the present disclosure. In the illustrated example the chamber arrangement 104 has a single-wafer cross flow arrangement and in this respect includes a chamber body 132, an injection flange 134, and an exhaust flange 136. In further respect, the chamber arrangement 104 also includes an upper heater element array 138, a lower heater element array 140, a divider 142, a substrate support 144, a support member 146, a shaft member 148, and a lift and rotate module 150. Although shown and described herein as including certain elements and having a specific arrangement in the illustrated example, it is to be understood and appreciated that the chamber arrangement 104 may include additional elements and/or exclude elements shown and described herein, or have a different arrangement than shown and described herein, and remain within the scope of the present disclosure.

The chamber body 132 is formed from a transmissive material 152 (e.g., transmissive to electromagnetic radiation within an infrared waveband) and has an upper wall 154, a lower wall 156, a first sidewall 158, and a second sidewall 160. The upper wall 154 extends between an injection end 162 and a longitudinally opposite exhaust end 164 of the chamber body 132. The lower wall 156 is spaced apart from the upper wall 154 by an interior 166 of the chamber body 132, extends between the injection end 162 and the exhaust end 164 of the chamber body 132, and is coupled to the upper wall 154 by the first sidewall 158 and the second sidewall 160. In certain examples, the transmissive material 152 may include a ceramic material. Non-limiting examples of suitable ceramic materials include quartz, fused silica, and sapphire. In accordance with certain examples, the chamber body 132 may include a plurality of external ribs extending about an exterior of the chamber body 132 and longitudinally spaced apart from one another between the injection end 162 and the exhaust end 164 of the chamber body 132. Although shown and described herein as having a planar shape, it is to be understood and appreciated that the chamber body 132 may have an arcuate or dome-like shape and remain within the scope of the present disclosure.

The injection flange 134 is connected to the injection end 162 of the chamber body 132, couples the precursor delivery arrangement 102 to the chamber body 132, and is configured to communicate the precursor 10 provided by the precursor delivery arrangement 102 (shown in FIG. 1) to the interior 166 of the chamber body 132. The exhaust flange 136 is connected to the exhaust end 164 of the chamber body 132, couples the chamber body 132 to the exhaust arrangement 106, and is configured to communicate the residual precursor and/or reaction products 18 issued by chamber arrangement 104 to the exhaust arrangement 106.

The upper heater element array 138 is supported above the chamber body 132 and is configured to communicate heat into the interior 166 of the chamber body 132 through the upper wall 154 of the chamber body 132, for example, radiantly using electromagnetic radiation within an infrared waveband transmitted by the transmissive material 152 forming the upper wall 154 of the chamber body 132. The lower heater element array 140 is similar to the upper heater element array 138, is additionally supported below the chamber body 132, and is configured to communicate heat into the interior 166 of the chamber body 132 through the lower wall 156 of the chamber body 132. In certain examples, the upper heater element array 138 may include a plurality of upper linear lamps, the lower heater element array 140 may include a plurality of lower linear lamps, and the plurality of lower linear lamps may be orthogonal relative to the plurality of upper linear lamps. In accordance with certain examples, the plurality of upper linear lamps may extend laterally between the first sidewall 158 and the second sidewall 160, the plurality of linear lamps longitudinally spaced apart from one another between the injection end 162 and the exhaust end 164 of the chamber body 132. It is also contemplated that the plurality of upper linear lamps may extend longitudinally between the injection end 162 and the exhaust end 164 of the chamber body 132 and be laterally spaced apart from one another between the first sidewall 158 and the second sidewall 160 and remain within the scope of the present disclosure. As will be appreciated by those of skill in the art in view of the present disclosure, either (or both) the upper heater element array 138 and the lower heater element array 140 may include bulb or spot lamp-type heater elements and remain within the scope of the present disclosure.

The divider 142 is formed from an opaque material 168 (e.g., a material opaque to electromagnetic radiation within an infrared waveband), is fixed within the interior 166 of the chamber body 132, and divides the interior 166 of the chamber body 132 into an upper chamber 170 and a lower chamber 172. The divider 142 further defines an aperture 174, the aperture 1742 fluidly coupling the upper chamber 170 to the lower chamber 172 of the interior 166 of the chamber body 132. The substrate support 144 is supported for rotation R about a rotation axis 176 extending through the aperture 174, is arranged at least partially within the aperture 174, and is configured to support a substrate during deposition of a layer onto a surface of the substrate (e.g., the substrate 2 during forming of the semiconductor structure 200 layer 14 onto an upper surface of the substrate 2). In this respect it is contemplated that the substrate support 144 may be formed from an opaque material (e.g., the opaque material 168) and optically coupled to at least one of the upper heater element array 138 and the lower heater element array 140 by the upper wall 154 and the lower wall 156 of the chamber body 132, respectively. In certain examples, the opaque material 168 may include a carbonaceous material, such as silicon carbide and/or bulk graphite by way of illustration and not limitation.

The support member 146 is arranged along the rotation axis 176 and within the lower chamber 172 of the chamber body 132, is fixed in rotation relative to the substrate support 144, and couples the substrate support 144 to the shaft member 148. The shaft member 148 is fixed in rotation relative to the support member 146, extends through the lower wall 156 of the chamber body 132 and into the environment external to the chamber body 132, and couples the substrate support 144 to the lift and rotate module 150 through the support member 146. The lift and rotate module 150 is operably connected to the substrate support 144 and is configured to rotate the substrate support 144 about the rotation axis 176 during deposition of the layer 14 onto the substrate 12. The lift and rotate module 150 may be further configured to seat and unseat substrates (e.g., the substrate 12) on the substrate support 144, for example, in cooperation with a gate valve 178 and substrate transfer robot 180. In certain examples, either (or both) the support member 146 and the shaft member 148 may be formed from a transmissive material, such as the transmissive material 152.

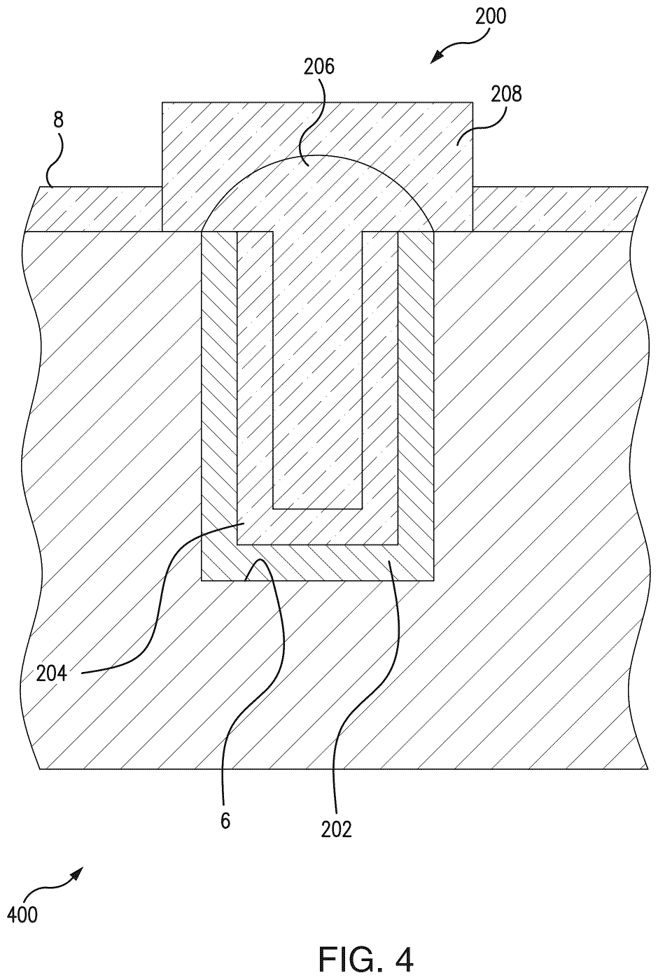

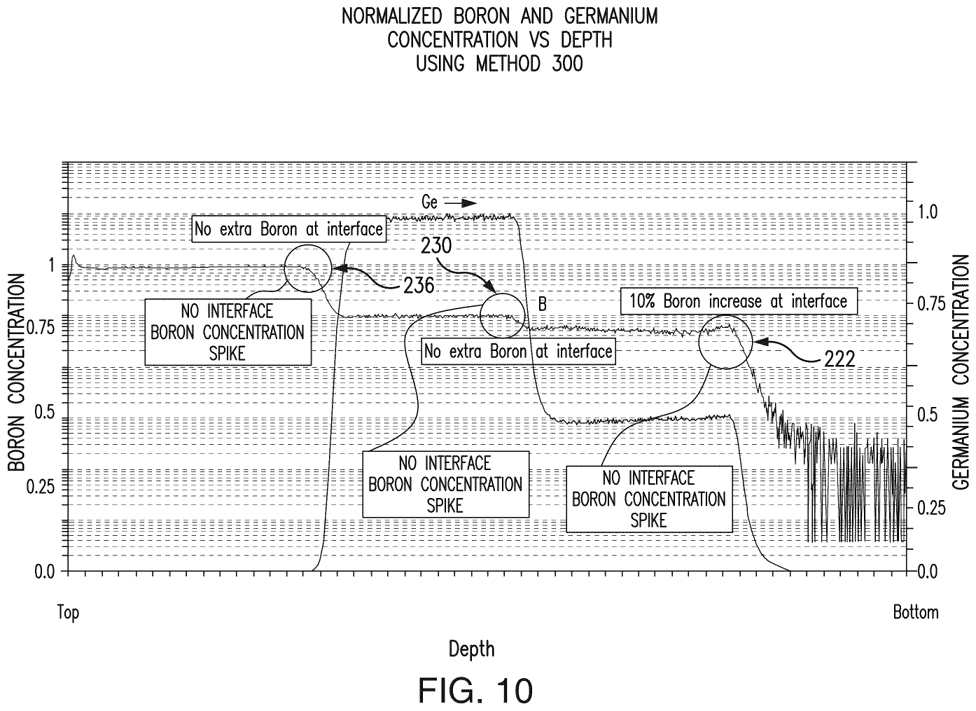

In the illustrated example the controller 108 includes a device interface 182, a processor 184, a user interface 186, and a memory 188. The device interface 182 couples the controller 108 to one or more of the precursor delivery arrangement 102, the chamber arrangement 104, and the exhaust arrangement 106, for example, through the wired or wireless link 110. The processor 184 is disposed in communication with the device interface 182 and the memory 188, and is operably connected to the user interface 186, for example, to receive input and/or provide user output therethrough. The memory 188 includes a non-transitory machine-readable medium having a plurality of program modules 190 recorded thereon that, when read by the processor 184, cause the processor 184 to execute certain operations. Among the operations are operations of a method 300 (shown in FIG. 10) of making a semiconductor structure, e.g., the semiconductor structure 200 (shown in FIG. 4), as will be described, the non-transitory machine-readable medium being a computer program product 192 in this respect. Although shown and described herein as including certain elements and having a specific arrangement in the illustrated example, it is to be understood and appreciated that the controller 108 may include additional elements and/or exclude elements shown and described herein, or have a different arrangement than shown and described herein, and remain within the scope of the present disclosure.

With reference to FIG. 4 and FIGS. 5-8, the semiconductor structure 200 and sequential (e.g., layer-by-layer) formation of the semiconductor structure 200 are shown. Referring to FIG. 4, the semiconductor structure 200 includes the substrate 2, a silicon-germanium (SiGe) layer 202, a first boron-doped SiGe (SiGe:B) layer 204, a second SiGe:B layer 206, and a boron-doped silicon (Si:B) layer 208. The substrate 2 is formed from a semiconductor material such as silicon, defines a trench 4, and has a silicon surface portion 6 and a dielectric surface portion 8. The trench 4 is defined within an upper surface of the substrate and is bounded at least in part by the silicon surface portion 6. The dielectric surface portion 8 is outside of the trench 4 and may, in certain examples, comprise (or consist of or consist essentially of) an oxide.

The SiGe layer 202 is arranged (e.g., deposited) within the trench 4, overlays the silicon surface portion 6 (e.g., on the bottom and sidewalls of the trench), and may be epitaxial with the silicon surface portion 6 of the substrate 2. The first SiGe:B layer 204 is also arranged (e.g., deposited) within the trench 4 (e.g., conformally overlaying the SiGe layer 202 overlaying the bottom of the trench 4 and sidewalls of the trench 4), additionally overlays the SiGe layer 202, and may further be epitaxial with the SiGe layer 202. The second SiGe:B layer 206 is further arranged (at least in part) within the trench 4 (e.g., may overfill the trench 4), overlays the first SiGe:B layer 204, and may be epitaxial with the SiGe layer 204. The Si:B layer 208 overlays the second SiGe:B layer 206, may be arranged at partially outside of the trench 4 (e.g., may cap the second SiGe:B layer 206), and may be epitaxial with the second SiGe:B layer 206. In certain examples the Si:B layer 208 may cap the second SiGe:B layer 206, the Si: layer 208 separating the second SiGe:B layer 206 from structures overlaying the Si:B layer 208. In accordance with certain examples, the semiconductor structure 200 may form a portion of a three-dimensional semiconductor device 400. In this respect the semiconductor structure 200 may be included in a source portion or a drain portion of a gate-all-around semiconductor device, a finFET semiconductor device, or a 3D DRAM semiconductor device.

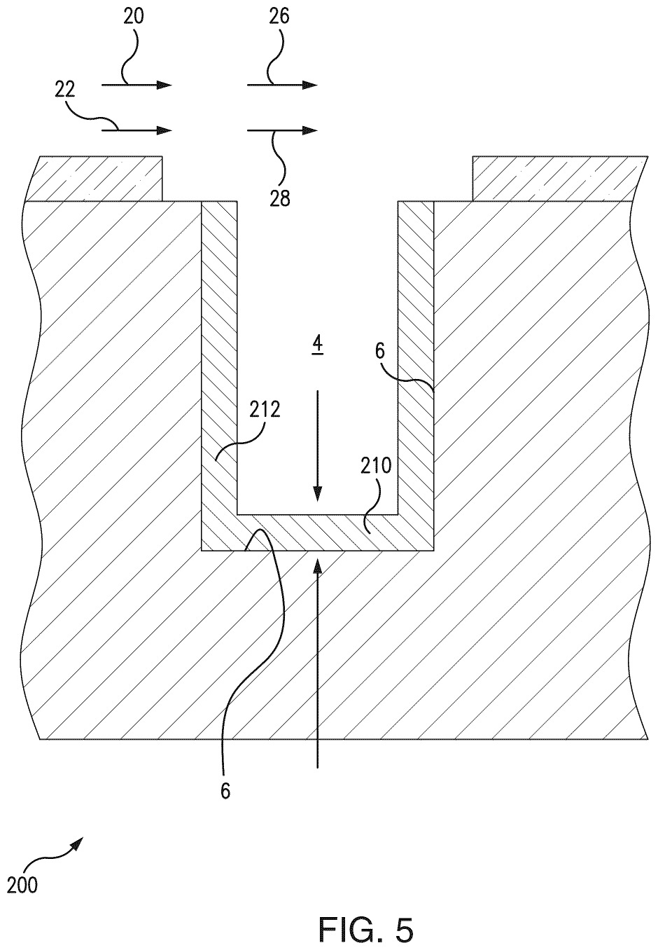

As shown in FIG. 5, the SiGe layer 202 may be deposited within the trench 4 and conformally onto (e.g., directly onto) the silicon surface portion 6. It is contemplated that the SiGe layer 202 be formed with a SiGe layer thickness 210 and a SiGe layer germanium content 212. The SiGe layer thickness 210 may be between about 25 angstroms and 100 angstroms, for example, between about 25 angstroms and about 50 angstroms, or between about 50 angstroms and about 75 angstroms, or even between about 75 angstroms and about 100 angstroms. The SiGe layer germanium content 212 may be between about 5 atomic weight % and about 55 atomic weight %, for example, between about 5 atomic weight % and about 25 atomic weight %, or between about 25 atomic weight % and about 40 atomic weight %, or even between about 40 atomic weight % and about 55 atomic weight %. In accordance with certain examples, the germanium concentration may be graded within the SiGe layer 202, concentration changing within the thickness of the SiGe layer 202. It is also contemplated that the germanium concentration may be constant within the SiGe layer 202 and remain within the scope of the present disclosure. Advantageously, forming the SiGe layer 202 with the SiGe layer thickness 210 and/or the SiGe layer germanium content 212 within these ranges may graduate strain within the semiconductor structure 200 due to lattice mismatch between the lattice defined by the silicon surface portion 6 and the SiGe layer 202, reducing (or eliminating) the tendency of crystallographic slip defects to form at a silicon surface-to-SiGe layer interface 214 due to strain associated with lattice mismatch.

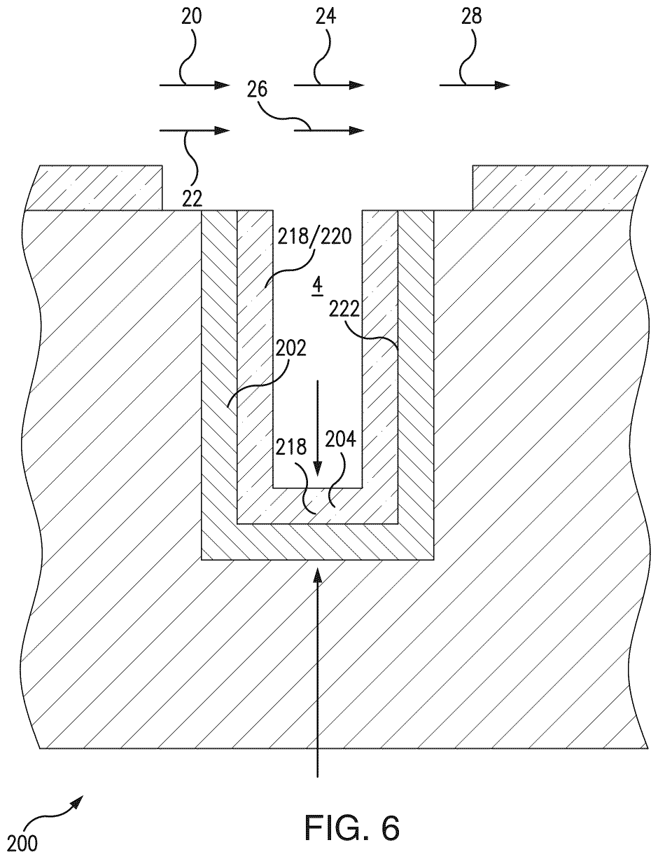

As shown in FIG. 6, the first SiGe:B layer 204 may be deposited within the trench 4 and conformally onto the SiGe layer 202. It is contemplated that the first SiGe:B layer 204 be formed with a first SiGe:B layer thickness 216, a first SiGe:B layer germanium content 218, and a first SiGe:B layer boron content 220. The first SiGe:B layer thickness 216 may be between about 25 angstroms and about 250 angstroms, for example, between about 25 angstroms and about 100 angstroms, or between about 100 angstroms and about 175 angstroms, or even between about 175 angstroms and about 250 angstroms. The first SiGe:B layer germanium content 218 may be between 5 atomic weight % and about 55 atomic weight %, for example, between about 5 atomic weight % and about 25 atomic weight %, or between about 25 atomic weight % and about 40 atomic weight %, or even between about 40 atomic weight % and about 55 atomic weight %. In certain examples, the first SiGe:B layer germanium content 218 may be less that the SiGe layer germanium content 212. In accordance with certain examples, the germanium concentration may be graded within the first SiGe:B layer 204, concentration changing within the thickness of the first SiGe:B layer 204. It is also contemplated that the germanium concentration may be constant within the first SiGe:B layer 204 and remain within the scope of the present disclosure. Advantageously, forming the first SiGe:B layer 204 with the first SiGe:B layer germanium content 218 and/or the first SiGe:B layer boron content 220 may graduate strain within the semiconductor structure 200, reducing (or eliminating) risk of crystallographic slip defects that could otherwise within the semiconductor structure 200, for example, at a SiGe layer-to-first SiGe:B layer interface 222 defined between the SiGe layer 202 and the first SiGe:B layer 204.

The first SiGe:B layer boron content 220 may be between about 1e¹⁸ atoms per cubic centime (cm³) and about 1e²² atoms per cm³, for example, between about 1e¹⁸ atoms per cm³ and about 1e¹⁹ atoms per cm³, or between about 1e¹⁹ atoms per cm³ and about 1e²⁰ atoms per cm³, or even between about 1e²⁰ atoms per cm³ and about 1e²¹ atoms per cm³. In certain examples, the first SiGe:B layer 204 may consist of or consist essentially of SiGe:B. In accordance with certain examples, the first SiGe:B layer boron content 220 may be substantially uniform throughout the first SiGe:B layer thickness 216. It is contemplated that, in certain examples, the first SiGe:B layer germanium content 218 may be substantially uniform throughout the first SiGe:B layer thickness 216. It is also contemplated that, in accordance with certain examples, the first SiGe:B layer 204 may be epitaxial with the SiGe layer 202. Advantageously, forming the first SiGe:B layer 204 with the first SiGe:B layer boron content 220 within these ranges may impart electrical properties into the semiconductor structure 200 that render the semiconductor structure 200 suitable for use as source and/or drain portions of semiconductor devices, such as in PMOS devices.

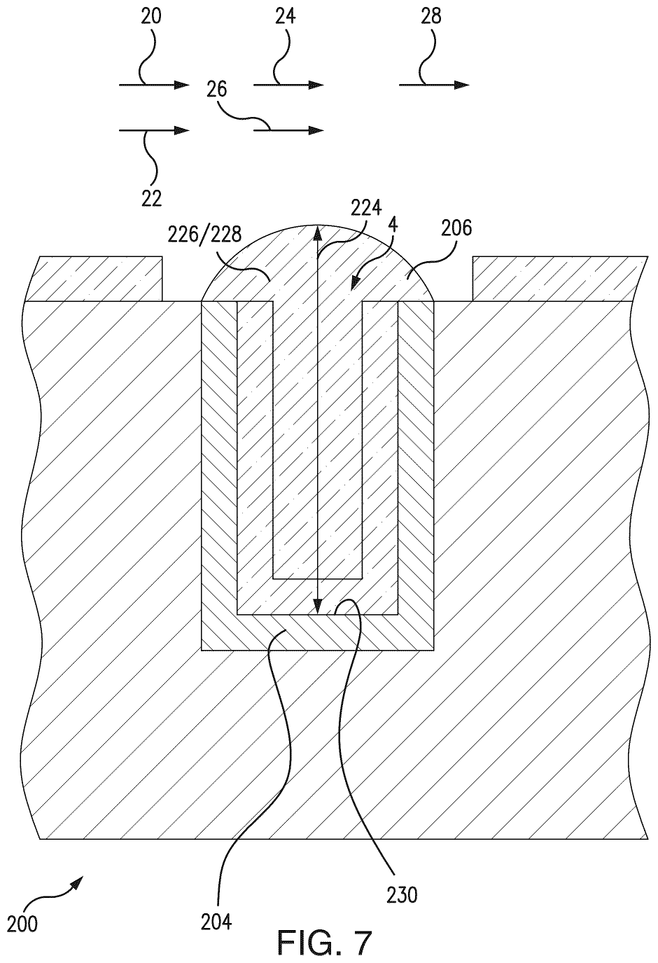

As shown in FIG. 7, the second SiGe:B layer 206 may be deposited within the trench 4 and conformally onto the first SiGe:B layer 204. It is contemplated that the second SiGe:B layer 206 be formed with a second SiGe:B layer thickness 224, a second SiGe:B layer germanium content 226, and a second SiGe:B layer boron content 228. The second SiGe:B layer thickness 224 may be between about 100 angstroms and about 1000 angstroms, for example, between about 100 angstroms and about 300 angstroms, or between about 300 angstroms and about 600 angstroms, or even between about 600 angstroms and about 1000 angstroms. The second SiGe:B layer germanium content 226 may be between about 3 atomic weight % and about 70 atomic weight %, for example, between about 3 atomic weight % and about 20 atomic weight %, or between about 20 atomic weight % and about 40 atomic weight %, or even between about 40 atomic weight % and about 70 atomic weight %. In certain examples, the second SiGe:B layer germanium content 226 may be less than the first SiGe:B layer germanium content 218. In accordance with certain examples, the germanium concentration may be graded within the second SiGe:B layer 206, concentration changing within the thickness of the second SiGe:B layer 206. It is also contemplated that the germanium concentration may be constant within the second SiGe:B layer 206 and remain within the scope of the present disclosure. Advantageously, forming the second SiGe:B layer 206 with the second SiGe:B layer germanium content 226 and/or the second SiGe:B layer boron content 228 may graduate strain within the semiconductor structure 200, reducing (or eliminating) risk of crystallographic slip defects that could otherwise within the semiconductor structure 200, for example, at a first SiGe:B layer-to-second SiGe:B layer interface 230 defined between the second SiGe:B layer 206 and the first SiGe:B layer 204.

The second SiGe:B layer boron content 228 may be between about 1e¹⁸ atoms per cm³ and about 1e²² atoms per cm³ for example, between about 1e¹⁸ atoms per cm³ and about 1e¹⁹ atoms per cm³, or between about 1e¹⁹ atoms per cm³ and about 1e²⁰ atoms per cm³, or even between about 1e²⁰ atoms per cm³ and about 1e²¹ atoms per cm³. In certain examples, the second SiGe:B layer 206 may consist of or consist essentially of SiGe:B. In accordance with certain examples, the second SiGe:B layer boron content 228 may be substantially uniform throughout the second SiGe:B layer thickness 224. It is contemplated that, in with certain examples, the second SiGe:B layer germanium content 226 may be substantially uniform throughout the second SiGe:B layer thickness 224. It is also contemplated that, in accordance with certain examples, the second SiGe:B layer 206 may be epitaxial with the first SiGe:B layer 204. Advantageously, forming the second SiGe:B layer 206 with the second SiGe:B layer boron content 228 within these ranges may, in cooperation with the first SiGe:B layer 204 impart electrical properties into the semiconductor structure 200 that render the semiconductor structure 200 suitable for employment as source and/or drain portions of semiconductor devices, such as in PMOS semiconductor devices.

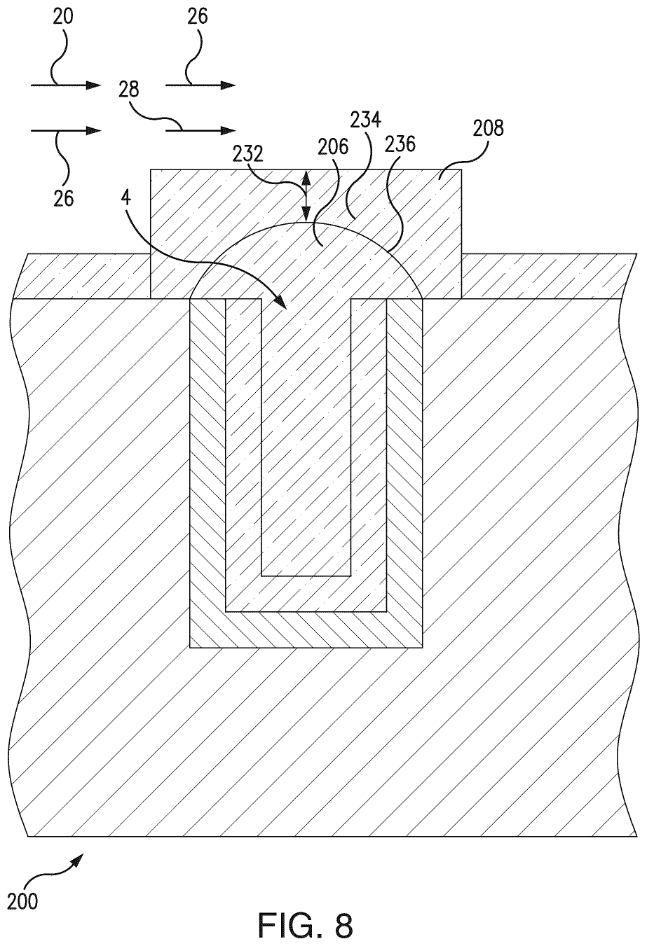

As shown in FIG. 8, the Si:B layer 208 overlays the second SiGe:B layer 206, a arranged at least partially within the trench 4, and has a Si:B layer thickness 232 and a Si:B layer boron content 234. The Si:B layer thickness 232 may be between about 50 angstroms and about 200 angstroms, for example, between about 50 angstroms and about 100 angstroms, or between about 100 angstroms and about 150 angstroms, or even between about 150 angstroms and about 200 angstroms. The Si:B layer boron content 234 may be between about 1e¹⁹ atoms per cm³ and about 1e²² atoms per cm³, for example, between about 1e¹⁹ atoms per cm³ and about 1e²⁰ atoms per cm³, or between about 1e²⁰ atoms per cm³ and about 1e²¹ atoms per cm³, or even between about 1e²⁰ atoms per cm³ and about 1e²¹ atoms per cm³. In certain examples, the Si:B layer 208 may be conformal with the second SiGe:B layer 206, for example, deposited directly onto the second SiGe:B layer 206. In accordance with certain examples, the Si:B layer 208 may be epitaxial with the second SiGe:B layer 206. It is contemplated that the Si:B layer 208 may be conformal with the second SiGe:B layer 206, for example by being deposited directly onto the second SiGe:B layer 206. It is also contemplated that, in accordance with certain examples, the Si:B layer 208 may be epitaxial with the second SiGe:B layer 206. Advantageously, forming the semiconductor structure 200 with the Si:B layer thickness 232 and the Si:B layer boron content 234 may limit (or eliminate) strain within the Si:B layer 208, limiting (or eliminating) risk crystallographic slip defects within the Si:B layer 206 potentially associated with lattice mismatch between crystalline structure of the second SiGe: layer 206 and crystalline structure of the Si:B layer 208.

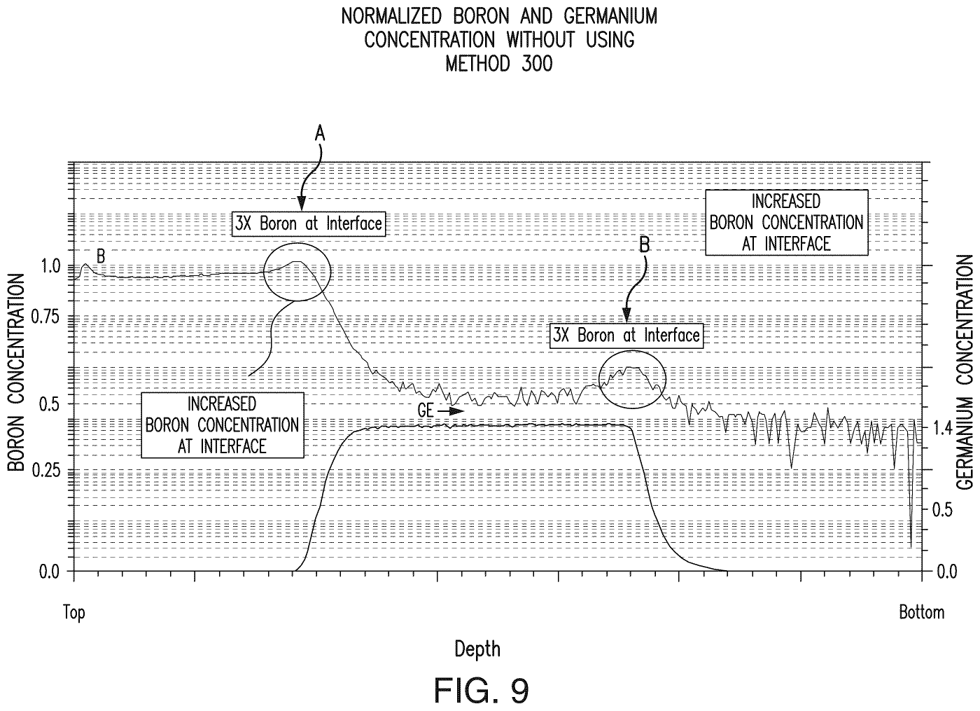

It is contemplated that a Si:B layer-to-second SiGe:B layer interface 236 be defined between the Si:B layer 208 and the second SiGe:B layer 206 within the semiconductor structure 200 (shown in FIG. 4). As shown in FIG. 10, the Si:B layer-to-second SiGe:B layer interface 236 may be substantially defect free, for example, with respect to variation in boron concentration variation at the interface (as shown with A in FIG. 9). In this respect it has been found that controlling rate of incorporation of germanium (Ge) and boron (B) during deposition of the second SiGe:B layer 206—and boron (B) during deposition of the Si:B layer 208 using sequential precursor flow throttling independent of silicon-containing precursor limits the defectivity at the interface due to variation in boron (B) concentration due to the tendency of boron (B) to compete with other constituents at the growth face exposed to the precursors during forming of the semiconductor structure 200. Without being bound by a particular theory or mode of operation, it is believed that the greater incorporation affinity of boron (B) relative to germanium (Ge) may locally increase boron concentration at the Si:B layer-to-second SiGe:B layer interface 236 relative to that within the second SiGe:B layer 206 and the Si:B layer 208. The increased boron (B) concentration at the Si:B layer-to-second SiGe:B layer interface 236 may, in certain semiconductor structures, alter electrical properties of the semiconductor structure. The increased boron (B) concentration may also locally alter lattice mismatch between the second SiGe:B layer 206 and the Si:B layer 208, locally increasing strain associated with the lattice mismatch and increasing risk that crystallographic slip defects develop in proximity to or at the Si:B layer-to second SiGe:B layer interface 236.

In certain examples, the Si:B layer-to-second SiGe:B layer interface 236 may be substantially defect free. The defect-free interface Si:B layer-to-second SiGe:B layer interface 236 may be formed by throttling precursor flow during deposition of the second SiGe:B layer 206 and the Si:B layer 208 according to relative incorporation affinity of layer constituents provided in the precursor flows. For example, flow of the boron-containing precursor to the chamber arrangement 104 (shown in FIG. 1), e.g., flow of the third precursor 24, may cease during deposition of the second SiGe:B layer 206. Flow of the germanium-containing precursor (e.g., the third precursor 24) may thereafter cease during deposition of the second SiGe:B layer 206. Flow of the silicon-containing precursor, e.g., the first precursor 20, may be increased (either in concert with decreasing of either or both the boron-containing precursor and the germanium-containing precursor or thereafter), and flow of the boron-containing precursor then resumed. Advantageously, this prevents boron concentration variation that could otherwise occur where the germanium-containing precursor and the boron-containing precursor shutoff coincident with one another, such as in processes where the atmosphere within the chamber arrangement employed for forming the semiconductor structure 200 is purged between deposition of the second SiGe:B layer 208 and deposition the Si:B layer 208.

As also shown in FIG. 10 in relation to FIG. 9. ceasing flow the boron-containing precursor prior to ceasing flow of the germanium-containing precursor causing available boron lingering within the atmosphere of the chamber arrangement 104 after cessation of the boron-containing precursor to be consumed progressively during deposition of the terminal portion of the second SiGe:B layer 208, preventing the lingering available boron competing with available germanium for incorporation into the developing second SiGe:B layer 208. As will be appreciated by those of skill in the art in view of the present disclosure, this causes the Si:B layer-to-second SiGe:B layer interface 236 by defined by boron depletion within the atmosphere of the chamber arrangement 104, and not by cessation of the deposition process by purging the atmosphere to drive out otherwise available boron and germanium lingering within the atmosphere. As will also be appreciated by those of skill in the art in view of the present disclosure, this can also limit the time required to form the semiconductor structure 200 as the silicon-containing precursor may be flowed continuously during deposition of both the second SiGe: layer 206 and the Si:B layer 208 (as well as the Si:B layer-to-second SiGe:B layer interface 236), improving throughput in relation to processes employing where a purge is employed between deposition of the second SiGe:B layer 206 and the Si:B layer 208.

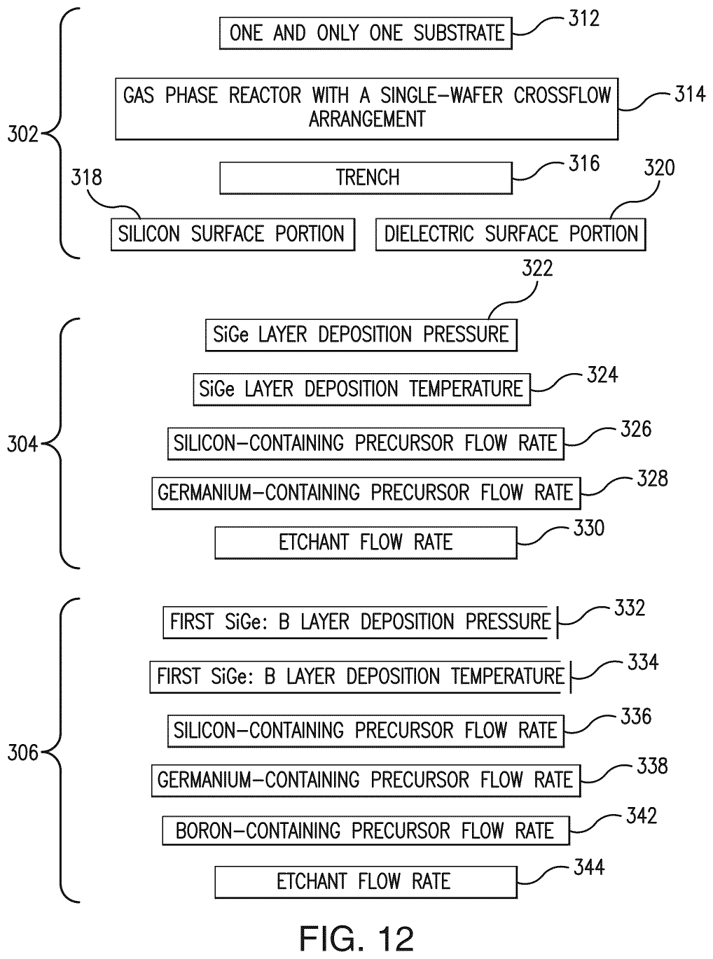

With reference to FIGS. 11-14, the method 300 of forming a semiconductor structure, e.g. the semiconductor structure 200 (shown in FIG. 1), is shown according to an illustrative and non-limiting example of the present disclosure. As shown in FIG. 11, the method 300 includes seating a substrate within a chamber arrangement of a semiconductor processing system, e.g., seating the substrate 2 (shown in FIG. 1) within the chamber arrangement 104 (shown in FIG. 1) of the semiconductor processing system 100 (shown in FIG. 1), as shown with box 302. The method 300 also includes depositing a silicon-germanium layer onto the substrate, e.g. the SiGe layer 202 (shown in FIG. 4), as shown with box 304. The method 300 further includes depositing a first boron-doped silicon-germanium layer onto the SiGe layer and a second boron-doped silicon-germanium layer on the first boron-doped silicon-germanium layer, e.g., the first SiGe:B layer 204 (shown in FIG. 4) onto the SiGe layer and the second SiGe:B layer 206 (shown in FIG. 4) onto the first SiGe:B layer, as shown with box 306 and box 308. It is contemplated that the method 300 additionally include depositing a boron-doped silicon layer onto the second SiGe:B layer, e.g., the Si:B layer 208 (shown in FIG. 4), and that a semiconductor device may be formed using the semiconductor structure, as shown with box 308 and box 310. As shown in FIG. 12, it is contemplated that a planar semiconductor device, a 3D DRAM semiconductor device, a finFET semiconductor device, and/or a GAA semiconductor device may be formed using the semiconductor structure, as shown with boxes 378-384.

As also shown in FIG. 12, seating 302 the substrate within the chamber arrangement may include seating one and one substrate within the chamber arrangement, as shown with box 312. Seating 302 the substrate within the chamber arrangement may include seating the substrate within a chamber arrangement having a single-wafer crossflow arrangement as shown with box 314. Seating 302 the substrate within the chamber arrangement may include seating a substrate having a trench defined within an upper surface of the substrate, e.g., the trench 4 (shown in FIG. 4), as shown with box 316. Seating 302 the substrate within the chamber arrangement may include seating a substrate having an exposed silicon surface portion and an exposed dielectric surface portion on the upper surface of the substrate, e.g., the silicon surface portion 6 (shown in FIG. 4) and the dielectric surface portion 8 (shown in FIG. 4), as shown with box 318 and box 320. It is contemplated that the dielectric surface may comprise an oxide, such as silicon oxide by way of illustration and not for limitation.

As further shown in FIG. 12, depositing 304 the SiGe layer may include depositing the SiGe layer at a predetermined SiGe layer deposition pressure, as shown with box 322. The predetermined SiGe layer deposition pressure may be between about 10 Torr and about 150 Torr, as also shown with box 322. Depositing 304 the SiGe layer may include depositing the SiGe layer at a predetermined SiGe layer deposition temperature, as shown with box 324. The predetermined SiGe layer deposition temperature may be between about 400 degrees Celsius and about 800 degrees Celsius, as also shown with box 324. Depositing 304 the SiGe layer may also include depositing the SiGe layer by flowing a silicon-containing precursor, e.g., the first precursor 20 (shown in FIG. 1), to the chamber arrangement, as shown with box 326. The silicon-containing precursor may be flowed at a SiGe layer silicon-containing precursor flow rate, for example, that is between about 10 standard cubic centimeters per minute (SCCM) and about 700 SCCM, as also shown with box 326. Depositing 304 the SiGe layer may further include coflowing a germanium-containing precursor to the chamber arrangement with the silicon-containing precursor, e.g., the second precursor 22 (shown in FIG. 2), as shown with box 328. The germanium-containing precursor may be flowed at a SiGe layer germanium-containing precursor flow rate, for example, that is between about 5 SCCM and about 70 SCCM, as also shown with box 328.

Depositing 304 the SiGe layer may additionally include coflowing an etchant, e.g., the etchant 26 (shown in FIG. 2), to the chamber arrangement with the silicon-containing precursor and the germanium-containing precursor, as shown with box 330. The etchant may be flowed to the chamber arrangement at a SiGe layer etchant flow rate, for example, at a SiGe layer etchant flow rate that is between about 10 SCCM and about 200 SCCM, as also shown with box 330. As will be appreciated by those of skill in the art in view of the present disclosure, the etchant 26 may provide selectivity to where on the substrate the SiGe layer is deposited, for example, by etching SiGe deposition on the dielectric surface portion 4 (shown in FIG. 4) more rapidly than SiGe deposition overlaying the silicon surface portion 6 (shown in FIG. 4). Advantageously, this can completely inhibit deposition of an amorphous material 30 (non-crystalline SiGe, SiGe:B, and/or Si:B) onto the dielectric surface portion 4 during forming of the semiconductor structure 200. As will also be appreciated by those of skill in the art in view of the present disclosure, a carrier/purge gas, e.g., the carrier/purge gas 28 (shown in FIG. 2), may be intermixed with one or more of the precursors provided to the chamber arrangement during deposition of the SiGe layer.

As further shown in FIG. 12, depositing 306 the first SiGe:B layer may include depositing the first SiGe:B layer at a predetermined first SiGe:B layer deposition pressure, as shown with box 332. The predetermined first SiGe:B layer deposition pressure may be between about 10 Torr and about 150 Torr, as also shown with box 332. Depositing 306 the first SiGe:B layer may include depositing the first SiGe:B layer at a predetermined first SiGe:B layer deposition temperature, as shown with box 334. The predetermined first SiGe:B layer deposition temperature may be between about 400 degrees Celsius and about 800 degrees Celsius, as also shown with box 334. Depositing 306 the first SiGe:B layer may include depositing the first SiGe:B layer by flowing the silicon-containing precursor to the chamber arrangement, as shown with box 336. The silicon-containing precursor may be flowed at a first SiGe:B layer silicon-containing precursor flow rate, for example at a first SiGe:B layer silicon-containing precursor flow rate that is between about 10 SCCM and about 700 SCCM, as also shown with box 336. Depositing 306 the first SiGe:B layer may include coflowing the germanium-containing precursor to the chamber arrangement with the silicon-containing precursor, as shown with box 338. The germanium-containing precursor may be flowed at a germanium-containing precursor flow rate that is between about 5 SCCM and about 50 SCCM, as also shown with box 338.

Depositing 306 the first SiGe:B layer may include coflowing a boron-containing precursor to the chamber arrangement with the silicon-containing precursor and the germanium-containing precursor, e.g., the third precursor 28 (shown in FIG. 2), as shown with box 340. The boron-containing precursor may be flowed at a first SiGe:B layer boron-containing precursor flow rate, for example, that is between about 0.25 SCCM and about 5 SCCM, as also shown with box 340. Depositing 306 the first SiGe:B layer may include coflowing the etchant to the chamber arrangement with the silicon-containing precursor and the germanium-containing precursor, as shown with box 342. The etchant may be flowed to the chamber arrangement at an first SiGe:B layer etchant flow rate, for example, at a first SiGe:B layer etchant flow rate that is between about 10 SCCM and about 40 SCCM, as also shown with box 342. As will be appreciated by those of skill in the art in view of the present disclosure, the etchant provided during deposition of the first SiGe:B layer may provide selectivity to where the first SiGe:B layer is deposited on the substrate, for example, by etching SiGe:B deposition on the dielectric surface portion of the substrate more rapidly than SiGe:B deposition overlaying the silicon surface portion of the substrate. As will also be appreciated by those of skill in the art in view of the present disclosure, the carrier/purge gas may be intermixed with one or more of the precursors provided to the chamber arrangement during deposition of the first SiGe:B layer.

As shown in FIG. 12, depositing 308 the second SiGe:B layer may include depositing the second SiGe:B layer at a predetermined second SiGe:B layer deposition pressure, as shown with box 346. The predetermined second SiGe:B layer deposition pressure may be between about 10 Torr and about 100 Torr, as also shown with box 346. Depositing 308 the second SiGe:B layer may include depositing the second SiGe:B layer at a predetermined second SiGe:B layer deposition temperature, as shown with box 348. The predetermined second SiGe:B layer deposition temperature may be between about 400 degrees Celsius and about 800 degrees Celsius, as also shown with box 348. Depositing 308 the second SiGe:B layer may include depositing the second SiGe:B layer by flowing the silicon-containing precursor to the chamber arrangement, as shown with box 350. The silicon-containing precursor may be flowed at a second SiGe:B layer silicon-containing precursor flow rate that is between about 10 SCCM and about 700 SCCM, as also shown with box 350. Depositing 308 the second SiGe:B layer may include coflowing the germanium-containing precursor to the chamber arrangement with the silicon-containing precursor, as shown with box 352. The germanium-containing precursor may be flowed at a germanium-containing precursor flow rate that is between about 10 SCCM and about 100 SCCM, as also shown with box 352. Depositing 308 the second SiGe:B layer may include coflowing the boron-containing precursor to the chamber arrangement with the silicon-containing precursor and the germanium-containing precursor, e.g., the third precursor 28 (shown in FIG. 2), as shown with box 354. The boron-containing precursor may be flowed to the chamber arrangement at a second SiGe:B layer boron-containing precursor flow rate, for example that is between about 3 SCCM and about 150 SCCM, as also shown with box 354.

Depositing 308 the second SiGe:B layer may include coflowing the etchant to the chamber arrangement with the silicon-containing precursor, the germanium-containing precursor, and the boron-containing precursor, as shown with box 356. The etchant may be flowed to the chamber arrangement at a second SiGe:B layer etchant flow rate, for example at a second SiGe:B etchant flow rate that is between about 10 SCCM and about 400 SCCM, as also shown with box 356. As will be appreciated by those of skill in the art in view of the present disclosure, the etchant may provide selectivity to where the second SiGe:B layer is deposited, for example, by etching SiGe:B deposition on the dielectric surface portion more rapidly than SiGe:B deposition overlaying the silicon surface portion of the substrate. As will also be appreciated by those of skill in the art in view of the present disclosure, the carrier/purge gas may be intermixed with one or more of the precursors provided to the chamber arrangement during deposition of the second SiGe:B layer.

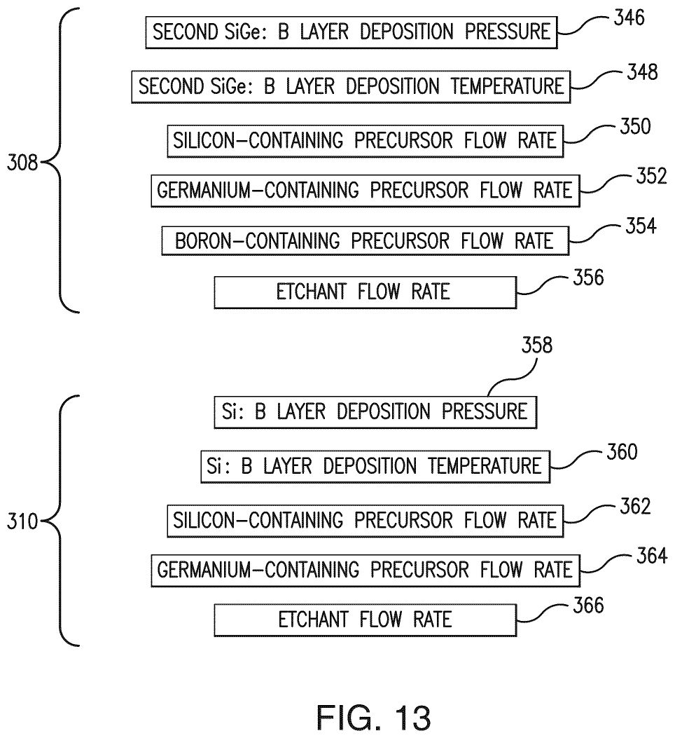

As also shown in FIG. 13, depositing 310 the Si:B layer may include depositing the Si:B layer at a predetermined second Si:B layer deposition pressure, as shown with box 358. The predetermined Si:B layer deposition pressure may be between about 10 Torr and about 100 Torr, as also shown with box 358. Depositing 310 the Si:B layer may include depositing the second SiGe:B layer at a predetermined Si:B layer deposition temperature, as shown with box 360. The predetermined Si:B layer deposition temperature may be between about 400 degrees Celsius and about 800 degrees Celsius, as also shown with box 360. Depositing 310 the Si:B layer may include depositing the Si:B layer by flowing the silicon-containing precursor to the chamber arrangement, as shown with box 362. The silicon-containing precursor may be flowed at a predetermined Si:B layer silicon-containing precursor flow rate that is between about 10 SCCM and about 700 SCCM, as also shown with box 362. Depositing 364 the Si:B layer may include coflowing the boron-containing precursor to the chamber arrangement with the silicon-containing precursor, as shown with box 364. The boron-containing precursor may be flowed at a predetermined Si:B layer boron-containing precursor flow rate, for example that is between about 3 SCCM and about 150 SCCM, as also shown with box 364.

In certain examples, depositing 310 the Si:B layer may include coflowing the etchant to the chamber arrangement with the silicon-containing precursor and the boron-containing precursor, as shown with box 366. The etchant may be flowed to the chamber arrangement at a predetermined Si:B layer etchant flow rate, for examples that is between about 10 SCCM and about 300 SCCM, as also shown with box 366. As will be appreciated by those of skill in the art in view of the present disclosure, the etchant provided during deposition of the Si:B layer may provide selectivity to where the Si:B layer is deposited on the substrate, for example, by etching Si:B deposition on the dielectric surface portion more rapidly than Si:B deposition overlaying the silicon surface portion of the substrate. As will also be appreciated by those of skill in the art in view of the present disclosure, the carrier/purge gas may be intermixed with one or more of the precursors provided to the chamber arrangement during deposition of the Si:B layer.

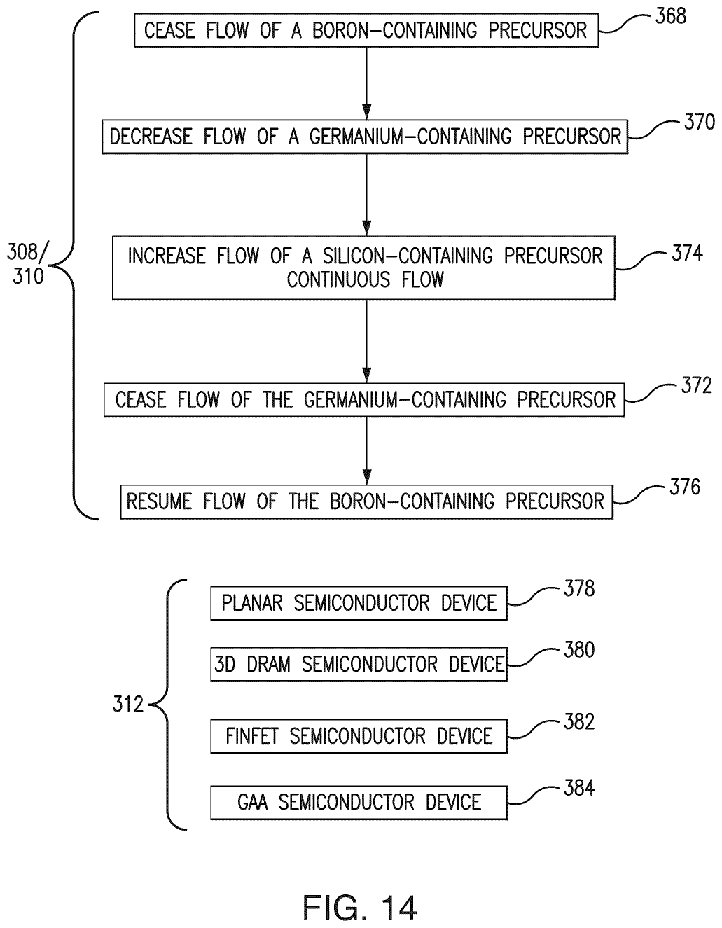

As shown in FIG. 14, depositing 306 the second SiGe:B layer may include ceasing flow of the boron-containing precursor during deposition of the second SiGe:B layer, as shown with box 368. In this respect it is contemplated that flow of the boron-containing to the chamber arrangement cease (or be ramped down to a predetermined flow rate and thereafter ceased by diversion to a vent) prior to defining a Si:B layer-to-second SiGe:B layer interface, e.g., the Si:B layer-to-second SiGe:B layer interface 326 (shown in FIG. 8), as also shown with box 368. In certain examples, deposition of the second SiGe:B layer may continue subsequent to cessation of the flow of the boron-containing precursor to the chamber arrangement, continuing deposition of the second SiGe:B layer consuming residual boron constituent resident within the atmosphere contained within the chamber arrangement housing the substrate and semiconductor structure being formed thereon, as further shown with box 368.

Depositing 306 the second SiGe:B layer may include decreasing flow rate of the germanium-containing precursor the chamber arrangement, as shown with box 370. Flow rate of the germanium-containing precursor may be decreased subsequent to cessation of flow of the boron-containing precursor to the chamber arrangement, as also shown with box 370. It is contemplated that deposition of the second SiGe:B layer may continue during decrease of flow, and/or subsequent to cessation of flow of the germanium-containing precursor to the chamber arrangement, the continued deposition of the second SiGe:B layer consuming residual germanium constituent resident within the atmosphere of the chamber arrangement. It is also contemplated that flow of the germanium-containing precursor to the chamber arrangement thereafter cease during deposition of the second SiGe:B layer, as shown with box 372. Deposition of the second SiGe:B layer may continue thereafter, consuming residual germanium-containing constituent within the chamber arrangement, the Si:B layer-to-second SiGe:B layer thereafter being defined when concentration of boron constituent and germanium constituent lingering in the atmosphere of the chamber arrangement is insufficient for further second SiGe:B layer deposition. Flow of the silicon-containing precursor to the chamber arrangement may increase during deposition of the second SiGe layer, for example coincident with cessation of flow of the boron-containing precursor to the chamber arrangement and/or coincident with decrease of the flow of germanium-containing precursor to the chamber arrangement, as shown with box 374.

Deposition 308 of the Si:B layer is accomplished by resuming flow of the boron-containing precursor subsequent to cessation of the germanium-containing precursor to the chamber arrangement, as shown with box 376. In certain examples, flow of the boron-containing precursor may resume subsequent to consumption of residual germanium constituent lingering within the atmosphere of the chamber arrangement (e.g., to a level where germanium constituent within the chamber arrangement is unable to support further growth of the second SiGe:B layer), as also shown with box 376. In accordance with certain examples, flow of the silicon-containing precursor may continue during deposition of both the second SiGe: layer and the SiB layer, as shown with box 376.

Although this disclosure has been provided in the context of certain embodiments and examples, it will be understood by those skilled in the art that the disclosure extends beyond the specifically described embodiments to other alternative embodiments and/or uses of the embodiments and obvious modifications and equivalents thereof. In addition, while several variations of the embodiments of the disclosure have been shown and described in detail, other modifications, which are within the scope of this disclosure, will be readily apparent to those of skill in the art based upon this disclosure. It is also contemplated that various combinations or sub-combinations of the specific features and aspects of the embodiments may be made and still fall within the scope of the disclosure. It should be understood that various features and aspects of the disclosed embodiments can be combined with, or substituted for, one another in order to form varying modes of the embodiments of the disclosure. Thus, it is intended that the scope of the disclosure should not be limited by the particular embodiments described above.

The headings provided herein, if any, are for convenience only and do not necessarily affect the scope or meaning of the devices and methods disclosed herein.

1. A method of making a semiconductor structure, comprising:
seating a substrate within a chamber arrangement;
depositing a boron-doped silicon germanium (SiGe:B) layer onto the substrate; and
depositing a boron-doped silicon (Si:B) layer onto the SiGe:B layer; wherein depositing the Si:B layer comprises:
ceasing flow of a boron-containing precursor to the chamber arrangement;
decreasing flow of a germanium-containing precursor to the chamber arrangement;
increasing flow of a silicon-containing precursor to the chamber arrangement;
ceasing, after increasing flow of the silicon-containing precursor, flow of the germanium-containing precursor to the chamber arrangement; and
resuming flow of the boron-containing precursor to the chamber arrangement.

2. The method of claim 1, wherein the SiGe:B layer has a SiGe:B layer boron concentration, wherein the Si:B layer has a Si:B layer boron concentration, and wherein the Si:B layer boron concentration is greater than the SiGe:B layer boron concentration.

3. The method of claim 1, further comprising depositing a silicon germanium (SiGe) layer onto the substrate, wherein the SiGe:B layer is deposited onto the SiGe layer.

4. The method of claim 1, further comprising flowing a silicon-containing layer precursor to the chamber arrangement continuously and without interruption during deposition of both the SiGe:B layer and the Si:B layer.

5. The method of claim 1, wherein the SiGe:B layer is a first SiGe:B layer and further comprising depositing a second SiGe:B layer onto the first SiGe:B layer, wherein the Si:B layer is deposited onto the second SiGe:B layer.

6. The method of claim 5, wherein the first SiGe:B layer has a first boron concentration, wherein the second SiGe:B layer has a second boron concentration, and wherein the second boron concentration is greater than the first boron concentration.

7. The method of claim 6, wherein the Si:B layer has a third boron concentration, and wherein the third boron concentration is greater than the second boron concentration.

8. The method of claim 6, wherein the first SiGe:B layer has a first germanium concentration, wherein the second SiGe:B layer has a second germanium concentration, and wherein the second germanium concentration is greater than the first germanium concentration.

9. The method of claim 5, wherein depositing the first SiGe:B layer and depositing the second SiGe:B layer comprises flowing a silicon-containing layer precursor to the chamber arrangement continuously and without interruption during deposition of both the first SiGe:B layer and the second Si:B layer.

10. The method of claim 1, wherein depositing the SiGe:B layer comprises flowing the boron-containing precursor to the chamber arrangement at a first boron-containing precursor flow rate, the method further comprising increasing flow rate of the boron-containing precursor to a second boron-containing precursor flow rate, the second boron-containing precursor flow rate greater than the first boron-containing precursor flow rate.

11. The method of claim 1, wherein the substrate has an upper surface defining a trench therein, and wherein depositing the SiGe:B layer comprises depositing the SiGe:B layer at least partially within the trench.

12. The method of claim 1, wherein the substrate has a silicon surface portion and a dielectric surface portion, the method comprising flowing an etchant to the chamber arrangement during deposition of the SiGe:B layer and deposition of the Si:B layer to etch the dielectric surface portion of the substrate.

13. The method of claim 1, further comprising forming a gate-all-around semiconductor device, a finFET semiconductor device, a planar semiconductor device, or a 3D DRAM semiconductor device using the SiGe:B layer and the Si:B layer.

14. The method of claim 1, further comprising defining an interface between the SiGe:B layer and the Si:B layer between ceasing flow of the boron-containing precursor and resuming flow of the boron-containing precursor to the chamber arrangement.

15. A semiconductor device comprising a semiconductor structure formed using the method of claim 1.

16. The semiconductor structure of claim 15, wherein the semiconductor structure comprises:
a silicon germanium (SiGe) layer overlaying the substrate;
a first SiGe:B layer overlaying the SiGe layer;
a second SiGe:B layer overlaying the first SiGe:B layer; and
a Si:B layer overlaying the second SiGe:B layer, wherein the second SiGe:B layer and the Si:B layer are defect-free at an interface of the second SiGe:B layer and the Si:B layer.

17. A semiconductor processing system, comprising:
a precursor delivery arrangement;
a chamber arrangement with a substrate support connected to the precursor delivery arrangement;
a controller operably connected to the precursor delivery arrangement and the chamber arrangement, the controller responsive to instructions recorded on a memory to:
seat a substrate within the chamber arrangement;
deposit a boron-doped silicon germanium (SiGe:B) layer overlaying the substrate;
deposit a boron-doped silicon (Si:B) layer overlaying the SiGe:B by:
ceasing a flow of a boron-containing precursor to the chamber arrangement;
decreasing a flow of a germanium-containing precursor to the chamber arrangement;
increasing a flow of a silicon-containing precursor to the chamber arrangement;
ceasing, after increasing the flow of the silicon-containing precursor, the flow of the germanium-containing precursor to the chamber arrangement; and
resuming the flow of the boron-containing precursor to the chamber arrangement after ceasing the flow of the germanium-containing precursor to the chamber arrangement.

18. The semiconductor processing system of claim 17, wherein the SiGe:B layer is a first SiGe:B layer, and wherein the instructions further cause the controller:
deposit a silicon germanium (SiGe) layer onto the substrate;
deposit the first SiGe:B layer onto the first SiGe layer;
deposit a second SiGe:B layer onto the first SiGe:B layer; and
deposit the Si:B layer onto the second SiGe:B layer.

19. The semiconductor processing system of claim 17, wherein the instructions further cause the controller to:
flow an etchant to the chamber arrangement during deposition of at least one of the SiGe layer, the first SiGe:B layer, the second SiGe:B layer, and the Si:B layer; and
etch a dielectric surface portion of the substrate during deposition of the at least one of the SiGe layer, the first SiGe:B layer, the second SiGe:B layer, and the Si:B layer overlaying a silicon surface portion of the substrate.

20. A computer program product, comprising:
a memory including a non-transitory machine-readable having instructions that cause a controller operably connected to a precursor delivery arrangement to:
seat a substrate within a chamber arrangement connected to the precursor delivery arrangement;
deposit a boron-doped silicon germanium (SiGe:B) layer overlaying the substrate; and
deposit a boron-doped silicon (Si:B) layer overlying the SiGe:B layer by:
ceasing a flow of a boron-containing precursor to the chamber arrangement;
decreasing a flow of a germanium-containing precursor to the chamber arrangement;
increasing a flow of a silicon-containing precursor to the chamber arrangement;
ceasing, after increasing the flow of the silicon-containing precursor, the flow of the germanium-containing precursor to the chamber arrangement; and
resuming the flow of the boron-containing precursor to the chamber arrangement after ceasing the flow of the germanium-containing precursor to the chamber arrangement.
